(19) United States
(12) Patent Application Publication
(10) Pub. No.: US 2006/0276006 A1
(43) Pub. Date: Dec. 7, 2006

(54) METHOD OF SEGMENTING A WAFER

(76) Inventors: Chen-Hsiung Yang, Taipei Hsien (TW); Shih-Feng Shao, Taipei Hsien (TW); Hong-Da Chang, Tai-Chung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/163,504

(22) Filed: Oct. 20, 2005

(30) Foreign Application Priority Data
Jun. 3, 2005 (TW) 094118351

(51) Int. Cl. H01L 21/30; H01L 21/00

(52) U.S. Cl. 438/455; 438/795

(57) ABSTRACT

A method of segmenting a wafer. A device wafer is provided, and a medium layer is formed on the upper surface of the device wafer. Then, a carrier wafer is provided, and the medium layer is mounted on the surface of the carrier wafer. Subsequently, a segment process is performed to form a plurality of dies, and meanwhile these dies are mounted on the medium layer. Thereafter, the carrier wafer is departed from the medium layer, the dies are bonded to an extendable film, and the medium layer is removed.

### BACKGROUND OF THE INVENTION

1. Field of the Invention

The present invention pertains to a method of segmenting a wafer, and more particularly, to a method of segmenting a wafer that can incorporate with auto wafer expansion and sorting process.

2. Description of the Prior Art

In semiconductor or MEMS device fabrication, a wafer is segmented to millions of dies after dozens or hundreds of processes. Each die is then packaged to a chip, and electrically connect to a circuit board.

With reference to FIG. 1, FIG. 1 is a schematic diagram illustrating a prior art segment process that uses a cutting apparatus to segment a wafer. As shown in FIG. 1, a device wafer 10 to be segmented is bonded to an extendable film 12, e.g. by a tape, and the extendable film 12 is meanwhile mounted on a support frame 14 so as to fix the position of the device wafer 10. After the device wafer 10 is aligned, the cutting apparatus uses a cutter 16 to cut the device wafer 10 into a plurality of dies 18 in accordance with predetermined scribe lines. Following that, a wafer expansion process is performed by extending the extendable film 12 to enlarge the gap between the dies 18 for the facility of successive wafer sorting process.

The above-described method that uses a cutting apparatus to cut a wafer is a very common way to segment a wafer. However, the throughput is very low as long as the die density of the device wafer 10 becomes higher. In addition, the width of the cutter 16 can no longer be ignored when the critical dimension of semiconductor process decreases. Under such a condition, using the cutter 16 may result in die chipping. Thus, etching becomes another choice.

With reference to FIG. 2, FIG. 2 is a schematic diagram illustrating another conventional method of segmenting a wafer by etching. As shown in FIG. 2, a device wafer 30 is provided, and the device wafer 30 is adhered to a support carrier 34 with a bonding layer 32. The device wafer 30 includes a photoresist pattern 36 for defining scribe lines on the surface. Subsequently, an anisotropic etching process is performed to etch the device wafer 30 not covered by the photoresist pattern 36 until the device wafer 30 is etched through. Consequently, a plurality of dies 38 are formed.

The above-described etching method can reduce the width of scribe lines, and therefore the die density of the device wafer 30 can be improved. However, the support carrier 34 is a firm structure e.g. a wafer. As a result, the photoresist pattern 36 and the bonding layer 32 must be removed in advance, and the wafer sorting process can only be performed manually. Under such a condition, the throughput is seriously influenced, and the dies 38 may be damaged due to human factor.

### SUMMARY OF THE INVENTION

It is therefore one object of the present invention to provide a method of segmenting a wafer to improve throughput.

According to the claimed invention, a method of segmenting a wafer is provided. The method includes the following steps:

providing a device wafer comprising a device region disposed on an upper surface of the device wafer;

forming a medium layer on the upper surface of the device wafer;

providing a carrier wafer, and mounting the medium layer on a surface of the carrier wafer so as to fix the device wafer on the carrier wafer;

performing a segment process from a bottom surface of the device wafer to form a plurality of dies, wherein the plurality of dies remain on the medium layer;

separating the carrier wafer from the medium layer, and bonding the dies on an extendable film; and

removing the medium layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a prior art segment process that uses a cutting apparatus to segment a wafer.

FIG. 2 is a schematic diagram illustrating another conventional method of segmenting a wafer by etching.

FIG. 3 to FIG. 11 are schematic diagrams illustrating a method of segmenting a wafer in accordance with a preferred embodiment of the present invention.

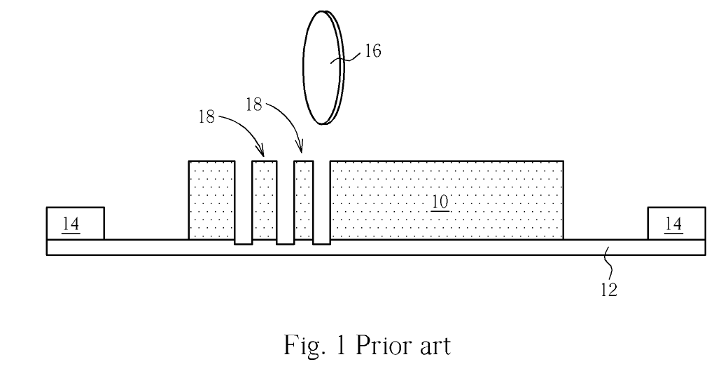

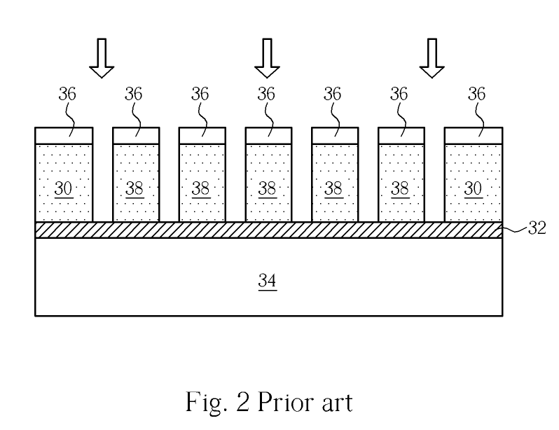

### DETAILED DESCRIPTION

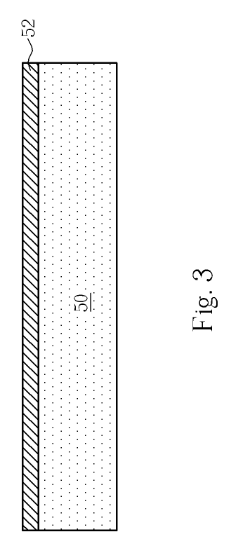

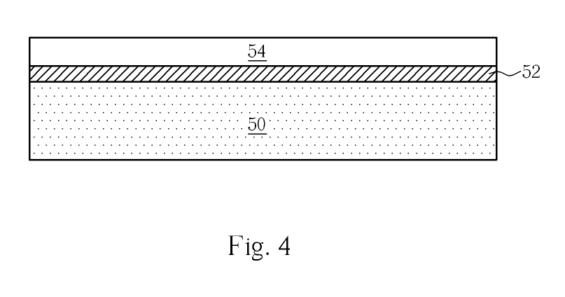

With reference to FIG. 3 to FIG. 11, FIG. 3 to FIG. 11 are schematic diagrams illustrating a method of segmenting a wafer in accordance with a preferred embodiment of the present invention. As shown in FIG. 3, a device wafer 50 to be segmented is provided. The device wafer 50 includes a device region 52 on the upper surface. As shown in FIG. 4, a medium layer 54 is formed on the device region 52 of the device wafer 50. The medium layer 54 serves as an intermedium for fixing the device wafer 50 to a carrier wafer, and also functions to protect the device wafer 50. In addition, since the medium layer 54 must be removed later, it is preferable to select a material that is easy to remove. In this embodiment, the material of the medium layer 54 may be benzocyclobutene (BCB), polyimide, epoxy, photoresist, dry film, etc, and the medium layer 54 is formed to the device wafer 50 by coating or bonding.

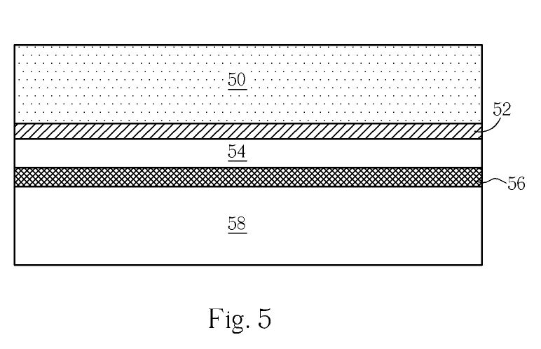

As shown in FIG. 5, the medium layer 54 is adhered to a carrier wafer 58 with a bonding layer 56. In this embodiment, the bonding layer 56 may be a thermal release tape or an UV tape. The thermal release tape can be removed by heating, while the UV tape can be released by an UV irradiation. The bonding layer 56 may also be other material that would not cause damages to the device wafer 50 and the medium layer 54. The carrier wafer 58 can be a semiconductor wafer, a glass wafer, or a quartz wafer. It is noted that if the bonding layer 56 is an UV tape, the carrier wafer 58 must be transparent e.g. a glass wafer or a quartz wafer.

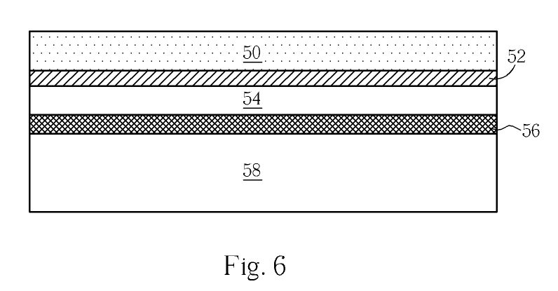

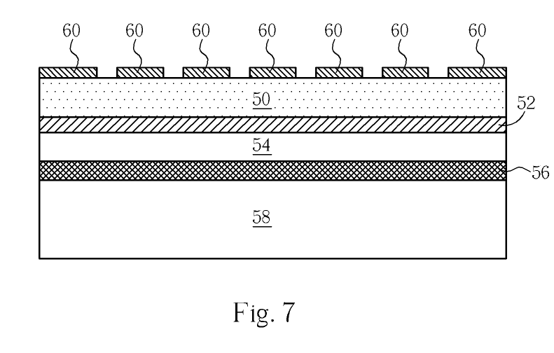

As shown in FIG. 6, a wafer thinning process, e.g. a polishing process or an etching process, is performed to thin the device wafer 50 from the bottom surface of the device wafer 50. It is appreciated that the wafer thinning process can also be carried out before the device wafer 50 is adhered to the carrier wafer 58. The wafer thinning process may even be omitted if the initial thickness of the device wafer 50 is not too thick. As shown in FIG. 7, a mask pattern 60 such as a photoresist pattern is formed on the bottom surface of the device wafer 50 to define scribe lines.

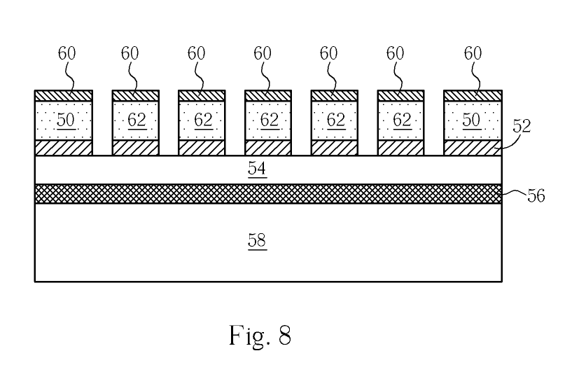

As shown in FIG. 8, a segment process is performed to remove the device wafer 50 not protected by the mask pattern 60 to form a plurality of dies 62. In this embodiment, the segment process is an anisotropic etching process e.g. a plasma etching process, and the device wafer 50 is etched from the bottom surface. After the segment process, the dies 62 still remain on the medium layer 54 so that the dies 62 do not fall off. In addition, the medium layer 54 can also serve as an etch stop layer.

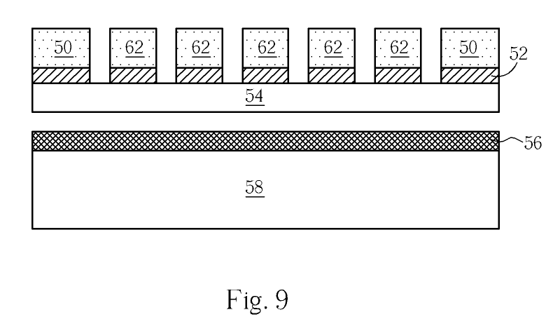

As shown in FIG. 9, the mask pattern 60 is removed, and the bonding layer 56 is released to separate the carrier wafer 58 from the medium layer 54. For example, if the bonding layer 56 is a thermal release tape, the device wafer 50 is heated to a temperature higher than the release temperature to remove the bonding layer 56. If the bonding layer 56 is an UV tape, UV light is irradiated from the bottom surface of the device wafer 50 to release the bonding layer 56.

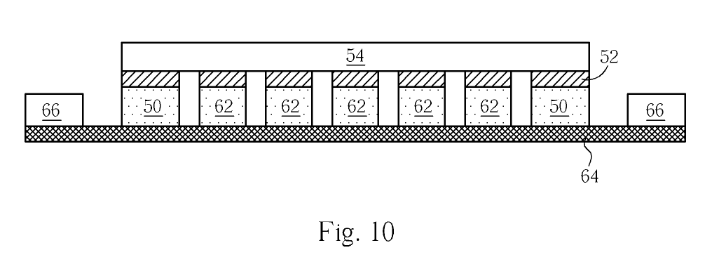

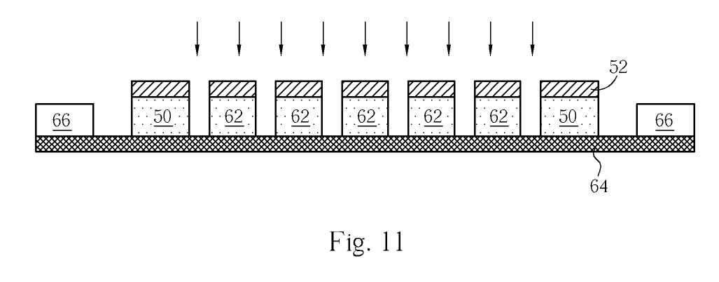

As shown in FIG. 10 and FIG. 11, the dies 62 are adhered to an extendable film 64 mounted on a support frame 66, and the medium layer 54 is removed from the surface of the dies 62. Accordingly, the dies 62 can be expanded and sorted automatically. It is appreciated that the step of adhering the dies 62 to the extendable film 64 and the step of removing the medium layer 54 may be swapped. Also, it is preferable to remove the medium layer 54 by a dry process, e.g. an oxygen plasma clean process or a supercritical carbon dioxide clean process, for preventing contamination of the dies 62.

In summary, the method of segmenting a wafer in accordance with the present invention uses a medium layer to transfer dies to an extendable film for the facility of successive wafer expansion and sorting process. In addition, the medium layer can be removed by a dry process so that the dies and the extendable film are not damaged. Conclusively, the method of the present invention can improve throughput, and reduce the risk of damaging the dies.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of segmenting a wafer comprising:
providing a device wafer comprising a device region disposed on an upper surface of the device wafer;
forming a medium layer on the upper surface of the device wafer;
providing a carrier wafer, and mounting the medium layer on a surface of the carrier wafer so as to fix the device wafer on the carrier wafer;
performing a segment process from a bottom surface of the device wafer to form a plurality of dies, wherein the plurality of dies remain on the medium layer;
separating the carrier wafer from the medium layer, and bonding the dies on an extendable film; and
removing the medium layer.

2. The method of claim 1, wherein bonding the dies on the extendable film is implemented prior to segmenting the carrier wafer from the medium layer.

3. The method of claim 1, wherein segmenting the carrier wafer from the medium layer is implemented prior to bonding the dies on the extendable film.

4. The method of claim 1, wherein the segment process comprises:
forming a mask pattern on the bottom surface of the device wafer to define scribe lines; and
performing an anisotropic etching process to etch the device wafer not covered by the mask pattern.

5. The method of claim 4, wherein the anisotropic etching process is a plasma etching process.

6. The method of claim 1, further comprising performing a wafer thinning process prior to performing the segment process.

7. The method of claim 1, further comprising performing an wafer expansion process subsequent to removing the medium layer.

8. The method of claim 1, wherein a material of the medium layer comprises BCB, polyimide, epoxy, photoresist or dry film.

9. The method of claim 1, wherein the medium layer is mounted on the carrier wafer with a thermal release tape.

10. The method of claim 1, wherein the medium layer is mounted on the carrier wafer with an UV tape.

11. The method of claim 1, wherein removing the medium layer is implemented by a dry process.

12. The method of claim 11, wherein the dry process is an oxygen plasma clean process.

13. The method of claim 11, wherein the dry process is a supercritical carbon dioxide clean process.
